(19) United States
(12) Patent Application Publication
(10) Pub. No.: US 2006/0170995 A1
(43) Pub. Date: Aug. 3, 2006

(54) Color image correction processing apparatus and color image correction processing method

(75) Inventor: Norimasa Ariga, Shizuoka-ken (JP)

Correspondence Address: FOLEY AND LARDNER LLP;SUITE 500, 3000 K STREET NW, WASHINGTON, DC, 20007, US

(73) Assignees: KABUSHIKI KAISHA TOSHIBA; TOSHIBA TEC KABUSHIKI KAISHA

(21) Appl. No.: 11/253,758

(22) Filed: Oct. 20, 2005

(30) Foreign Application Priority Data
Oct. 20, 2004 (JP) 2004-305935

(51) Int. Cl. G03F 3/08

(52) U.S. Cl. 358/518

(57) ABSTRACT

A color image correction processing apparatus firstly generates color modification processing data in a color modification processing data generating section from the data of the first color space in a color space transformation table that relates the first color space defining the values of the colors of the input image data to the second color space defining the values of the colors of the output image data. It then modifies the generated color modification processing data in a color modification processing data modifying section and executes a color space transformation process in a color space transforming section to acquire color modification history data. Then, the color image correction processing apparatus prepares a new color space transformation table, using the color modification history data. Then, it acquires color-modified output image data by executing a color space transformation process on the input image data, using the newly prepared color space transformation table. The acquired color modification history data are stored along with information for identifying the outcome of the most recent color modification process.

### BACKGROUND OF THE INVENTION

1. Field of the Invention

This invention relates to a color image correction processing apparatus and a color image correction processing method. More particularly, the present invention makes it possible to reduce the processing time necessary for correcting a color image and quickly return to a past correction step when adjusting a color image.

2. Description of the Related Art

The number of people who edit the digital images picked up by means of image pickup apparatus such as digital cameras according to their taste, using computers, has been increasing in recent years. Particularly, as for colors, an operator who is editing images adjusts colors mostly on trial and error basis before outputting images by way of an output device in order to acquire high quality images.

Images are processed on pixel by pixel basis in conventional color adjustment processes. The number of pixels contained in an image is enormous and the trend for higher resolutions in recent years has accelerated the increase in the number of pixels of an image. For example, the number of pixels of an image is about 310,000 according to the VGA standard and about 790,000 according to the XGA standard for computer displays. In the case of an image printed on the entire surface of an A4-size sheet of paper by means of a 0.600 dpi printer, the number of pixels on the A4-size sheet exceeds 30 millions. In the color adjustment process, it is necessary to compare the color to be adjusted with the colors existing in a color space transformation table to see the proximity of the color and each of the colors in the color space transformation table. A memory of a large storage capacity is required to execute such a comparing process on the color to be adjusted for each of the huge number of pixels contained in an image. Therefore, such a color adjustment process is extremely time-consuming.

Additionally, a color adjustment process is not completed by a single operation. Normally, adjustment operations of a number of different types are conducted for a number of times. For example, in a color adjustment process, the brightness of an entire image may be reduced and subsequently the flesh color of a protagonist in the image may be turned bright and clear while the flesh colors of other persons in the image may be turned bright only slightly. In such a color adjustment process, a desired image can scarcely be obtained without going back to a certain processing step in the past and repeating the same processing steps from that step. In other words, colors have to be adjusted for a number of times and some of the processing steps have to be repeated frequently before a desired image is obtained.

When going back to a certain processing steps, a predetermined adjustment status needs to be restored by using the history of adjustment in the past. Conventionally, the image that is obtained by each adjustment process is preserved or the adjustment method and the parameters and other factors that are used for each adjustment process are recorded in order to restore a predetermined adjustment status if necessary.

However, the technique of preserving the image that is obtained by each adjustment process requires a memory having a vast storage capacity for the purpose of preserving the obtained images.

With the technique of recording the adjustment method and the parameters that were used with the adjustment method as adjustment history, the parameters that were used for the adjustment process are recorded and therefore it is possible to obtain the image of a desired adjustment step in the past by going back to that step through the past adjustment steps from the current adjustment step on a step by step basis. However, if there is an irreversible adjustment step on the way, it is no longer possible to go further back from that step. Then, it is not possible to obtain the image of the desired adjustment step. Additionally, with this technique, all the adjustment process has to be repeated even if the operator wants to go back only to the immediately preceding adjustment step. Therefore, the adjustment process using this technique is highly time-consuming.

Jpn. Pat. Appln. Laid-Open Publication No. 2000-4369 discloses a technique of using an adjustment method and history of use of parameters. However, the disclosed technique is intended to define new parameters in order to efficiently conduct an operation of modifying a color space transformation table, using the data obtained by executing an averaging process, for example, on the adjustment parameters of the past adjustment steps, and hence it does not dissolve the above identified problems. Furthermore, the above-cited prior art document does not suggest anything for dissolving the above identified problems.

### BRIEF DESCRIPTION OF THE DRAWINGS

The accompanying drawings, which are incorporated in and constitute a part of the specification, illustrate presently preferred embodiments of the invention:

FIG. 1 is a schematic block diagram of a system that can be realized by applying an embodiment of color image correction processing apparatus according to the invention, illustrating the configuration thereof;

FIG. 2 is a schematic illustration of a selection image that can be used with a color modification method for an embodiment of color image correction processing apparatus according to the invention;

FIG. 3 is a schematic illustration of an operation image that can be used with modification method 1 for an embodiment of color image correction processing apparatus according to the invention;

FIG. 4 is a schematic illustration of an operation image that can be used with modification method 2 for an embodiment of color image correction processing apparatus according to the invention;

FIG. 5 is a schematic illustration of the hardware configuration that can be used for an embodiment of color image correction processing apparatus according to the invention;

FIG. 6 is a schematic illustration of the data region that is secured in a RAM for an embodiment of color image correction processing apparatus according to the invention;

FIG. 7A is an example of color space transformation table;

FIG. 7B is an illustration of color modification processing data that can be generated from the color space transformation table of FIG. 7A;

FIG. 7C is an illustration of color modification processing data that can be obtained by modifying the color modification processing data illustrated in FIG. 7B;

FIG. 7D is an illustration of color modification processing data that can be obtained by color space transformation of the color modification processing data illustrated in FIG. 7C;

FIG. 7E is an example of color space transformation table that can be prepared anew;

FIG. 8 is an example of color modification history data list that can be used for an embodiment of the present invention;

FIG. 9 is a schematic functional block diagram of an embodiment of color image correction processing apparatus according to the invention;

FIG. 10 is a flowchart of the operation of an embodiment of color image correction processing apparatus according to the invention, illustrating the general procedure thereof;

FIG. 11 is a flowchart of a color space transformation process that can be used for an embodiment of the present invention;

FIG. 12 is a flowchart of a color modification process that can be used for an embodiment of the present invention, illustrating the general procedure thereof;

FIG. 13 is an example of color modification history data list that can be used for an embodiment of the present invention;

FIG. 14 is a flowchart of a modification process for color modification processing data that can be used for an embodiment of the present invention;

FIG. 15 is a schematic illustration of the outcome of modification of color modification processing data obtained by means of modification method 1 for an embodiment of the present invention;

FIG. 16 is a schematic illustration of the outcome of modification of color modification processing data obtained by means of modification method 2 for an embodiment of the present invention; and

FIG. 17 is a flowchart of a return process that can be used for an embodiment of the present invention.

### DETAILED DESCRIPTION OF THE INVENTION

Throughout this description, the embodiments and examples shown should be considered as examples, rather than limitations on the apparatus of the present invention.

Now, an embodiment of the present invention will be described in greater detail by referring to the accompanying drawings.

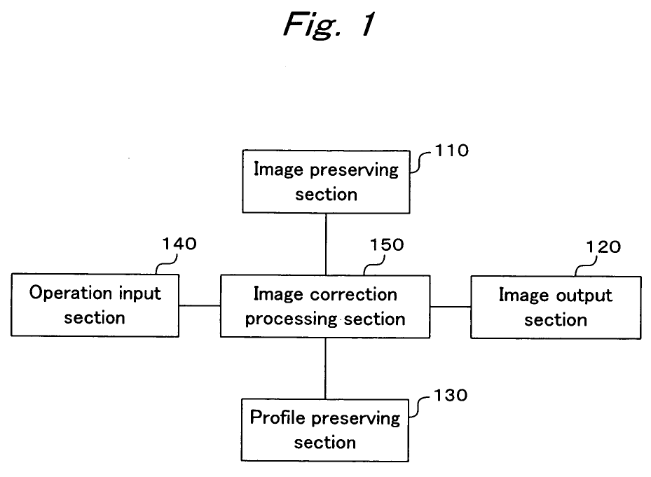

FIG. 1 is a schematic block diagram of a system that can be realized by applying an embodiment of color image correction processing apparatus according to the invention, illustrating the configuration thereof. In the instance of the illustrated system, an image preserving section 110 that preserves the input image data of a plurality of images whose outputs are to be adjusted, a color image output section 120 that outputs the output image data prepared by the color image correction processing apparatus, a profile preserving section 130 that preserves the profiles of the color image output section and an operation input section 140 where the operator operates for a color image adjustment process are connected to a color image correction processing apparatus 150 for modifying the color space transformation table obtained from the profiles, transforming the input image data by means of the modified color space transformation table and outputting the transformed input image data as output image data.

Assume here that the color information of the input image that is preserved in the image preserving section 110 does not depend on the image input/output device and is expressed by values in the space of the Lab Colorimetric System of the CIE (Commission Internationale d'Eclarirage) that is highly affinitive for the visual sense of human being. In the CIE Lab Colorimetric System, colors are expressed by means of three element of L*, a* and b*. The value of L* represents the lightness and those of a* and b* represent the hue and the saturation (brightness) of an image. Note that Lab values are used in a latter part of this document, * is omitted in the following description for the purpose of convenience so that L*, a* and b* are expressed respectively by L, a and b. It may be needless to say that the functions and the effects of the present invention are present if the color information of input images that are preserved in the image preserving section 110 is that of a calorimetric system other than the Lab system such as the XYZ system or the UVW system. The input images that are preserved in the image preserving section 110 may include so-called patch images as reference images for adjusting the colors of images.

The color image output section 120 is a means that makes the image data processed by the color image correction processing apparatus recognizable to the visual sense of human being. In other words, color displays and color printing means correspond to the color image output section. For the purpose of the present invention, color printing means include color printers as well as multi-function peripherals (MFPs) that have both a copy feature and a FAX feature. However, unless noted otherwise, the color image output section is described in terms of a display in the embodiments that are described below, although the functions and the effects of the present invention are present if the color image output section is a color printing means.

The profiles of the color image output section preserved in the profile preserving section 130 include color space transformation parameters that indicate the color gamut of the color image output section and the corresponding relationship between the values of colors in the color space specific to the color image output section and the values of colors in other color spaces. If a color image correction processing apparatus according to the invention comprises a single color image output section, the attributes of the input image to be subjected to a color modification process are diversified so that the profile preserving section 130 can preserve a plurality of profiles. Therefore, the color image correction processing apparatus can use an appropriate profile selected from the plurality of profiles. The color space that is specific to the device is generally that of RGB (red, green and blue) when the color image output section is a color display, whereas the color space that is specific to the device is generally that of CMYK (cyan, magenta, yellow and black) or CMY when the color image output section is a color printing means. As pointed out earlier, it is assumed that the color information of the input image is expressed by values in the space of the Lab Colorimetric System and, unless noted otherwise, the color image output section is described in terms of a display. Thus, the color space transformation parameters indicate the corresponding relationship between the color value in the Lab space and the color value in the RGB space for each of a plurality of colors. However, it may be needless to say that the functions of the present invention work if color space transformation parameters obtained by combining other color spaces are used. Color space transformation parameters can be expressed in the form of a table or a matrix. For the purpose of the present invention, color space transformation parameters take the form of a table, which is a so-called color space transformation table. Additionally, correction history information can be preserved in the profile preserving section 130.

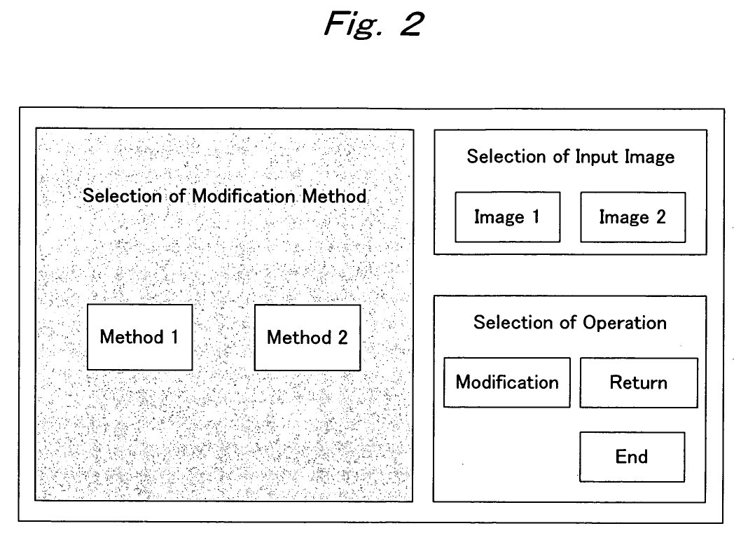

The operation input section 140 is designed to be used by the operator when he or she inputs adjustment operation information necessary for a color image correction process. The input adjustment operation information is transmitted to the color image correction processing apparatus 150. The adjustment operation will be described below by way of an example. The operation input section 140 includes a touch panel adapted to display and input operations so as to allow the operator to conduct adjustment operations. As the system is activated, a selection image for prompting the operator to select a color modification method is displayed as shown in FIG. 2.

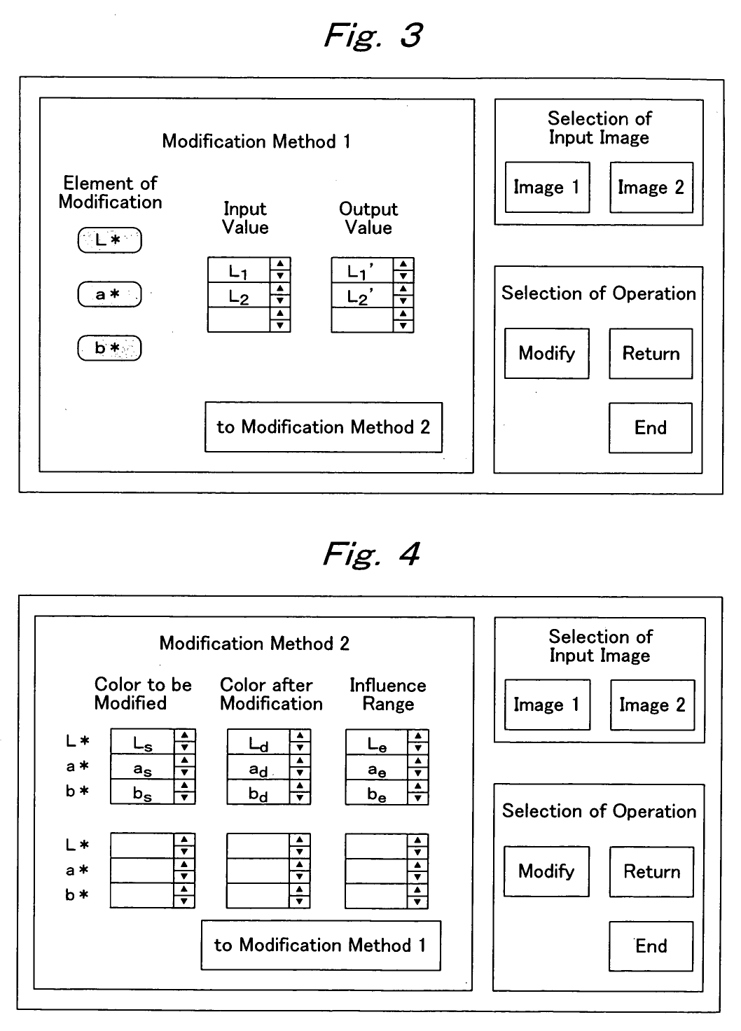

As button [Method 1] is depressed, an image for an operation with the first modification method is displayed as shown in FIG. 3. The first modification method is a method of modifying only one or the three color elements of L*, a* and b*. The operator selects the lightness (L*) as the color element to be modified by depressing button [L*]. Then, the operator inputs the value (L) of L* to be modified. The operator also defines the value (L′) of L* to be output when a color having the lightness of L is input. The operator can define a set of input and output values or a plurality of sets of input and output values. FIG. 3 shows an image that allows the operator to specify up to three sets of input and output values as an example. The input and output values of the color element to be modified are color modification parameters for the first modification method.

As button [Method 2] is depressed, on the other hand, an image for an operation with the second modification method is displayed as shown in FIG. 4. The second modification method is a method of modifying a color in a specified range that is centered at a Lab value to a color centered at another Lab value. The operator inputs the Lab value at the center of the range of the color to be modified in the [Color to be Modified] section, the Lab value at the center of the modified color in the [Color after Modification] section and the half width of the range of the color to be modified in the [Influence Range] in FIG. 4. The operator can input a plurality of sets of Lab values before and after modification and an influence range. FIG. 4 shows an image in which the operator can specify up to two such sets. Each of the color modification parameter values increases or decreases each time the operator depresses the upwardly directed triangular mark or the downwardly directed triangular mark, whichever appropriate, in the image for an operation with the first modification method or with the second modification method. The Lab value at the center of the range of the color to be modified, the Lab value at the center of the modified color and the half width of the range of the color to be modified are the color modification parameters for the second modification method.

If the modification method and the color modification parameters that are used for a color modification process is appropriate or not can be judged by seeing the image output from the color image output section. While two modification methods are described above, it may be needless to say that they may be modified appropriately in various different ways so long as the functions of the present invention work.

As [Image 1] button or [Image 2] button is depressed in the input image selection section, the operation input section 140 transmits the input image selection information to the color image correction processing apparatus 150. While the number of images from which the operator can select is two in FIGS. 2 through 4, it may be actually so arranged that the operator can select an image out of a much larger number of images.

As [Return] button of [End] button is depressed in the operation selection section, the operation input section 140 transmits the operation selection information to the color image correction processing apparatus. As [Modify] button is depressed, the operation input section 140 transmits the information on the selected modification method and the information on the defined color modification parameters to the color image correction processing apparatus 150.

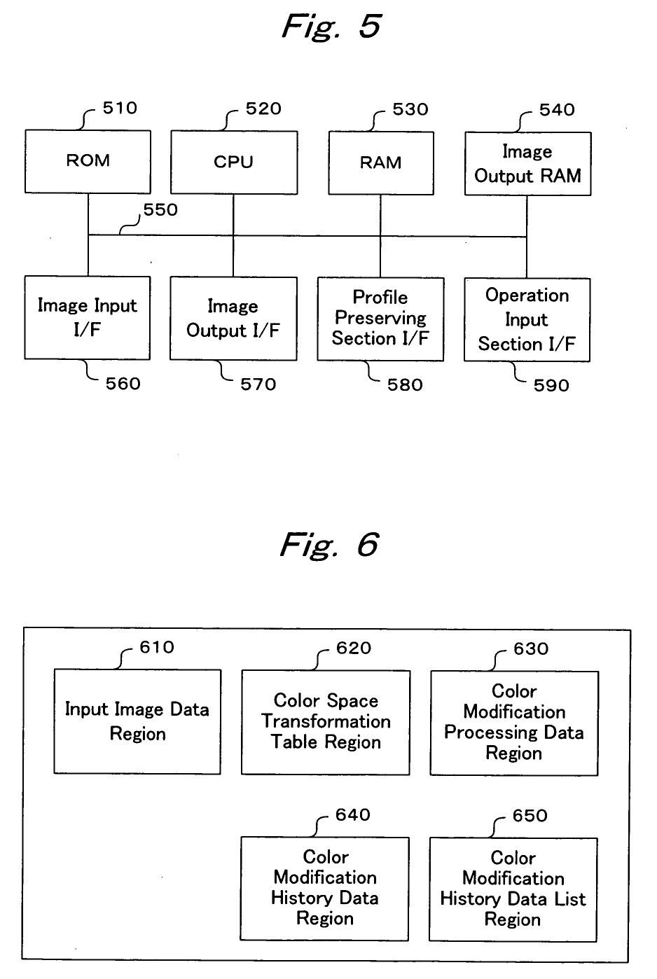

FIG. 5 is a schematic illustration of the hardware configuration that can be used for the color image correction processing apparatus 150. Referring to FIG. 5, the color image correction processing apparatus 150 comprises a ROM 510 that stores a processing program, a CPU 520 that executes processing operations according to the processing program, a RAM 530, an image output RAM 540 that stores output image data and interfaces (I/F) for peripheral components as shown in FIG. 1, which are connected to each other by way of a bus 550. The interfaces for peripheral components include image input I/F 560 for taking in input image data from the image preserving section 110, image output I/F 570 for transferring image data from the image output RAM 540 to the color image output section 120, profile preserving section I/F 580 for taking in profiles from the parallel preserving section 130 and operation input section I/F 590 for receiving the adjustment operation information that the operator inputs. Note that the RAM 530 may be provided with the function of the image outputting RAM 540.

As shown in FIG. 6, at least input image data region 610 for storing input image data, color space transformation table data region 620 for storing the data of the color space transformation table, color modification processing data region 630 for storing data for color modification processes, color modification history data region 640 for storing a plurality of color modification history data and color modification history data list region 650 for storing a color modification history data list are secured in the RAM 530. Now, the meanings of the terms used for the above listed types of data that are stored in the RAM 530 will be explained below.

No explanation will be needed for input image data.

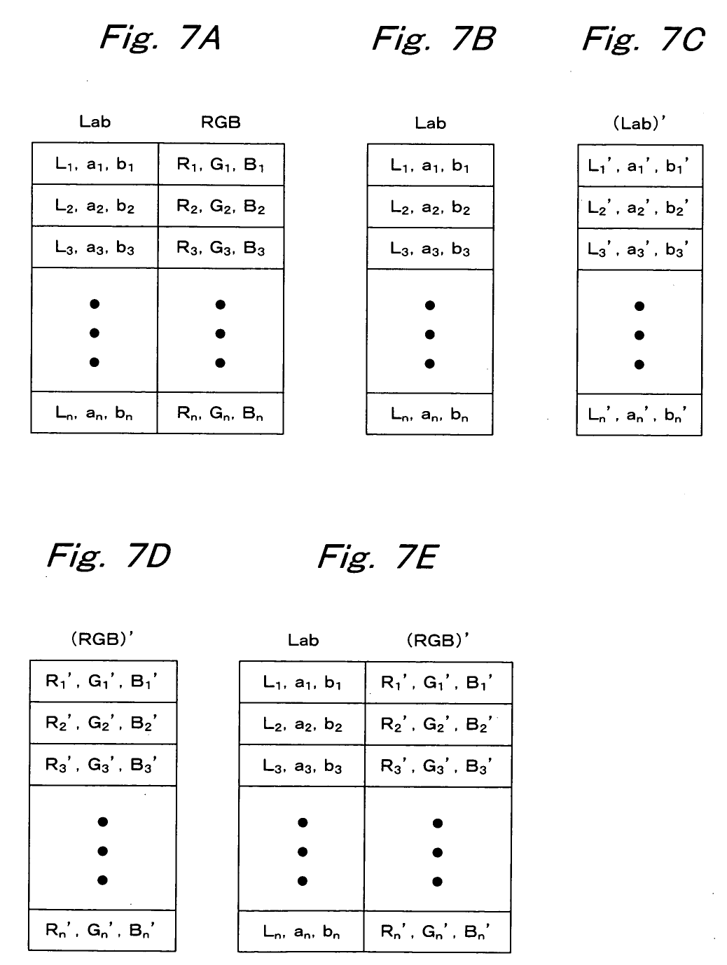

Data of the color space transformation table will be described below by referring to the example illustrated in FIG. 7A. A color space transformation table shows the corresponding relationship between the value of the first color space that defines the value of the color of the input image and the value of the second color space that defines the value of the color of the output image for each of n different colors. In this embodiment, each of the colors of the input image is expressed by a Lab value and each of the colors of the output image is expressed by an RGB value when the color image output section 120 is a color display. In short, the first and second color spaces are a Lab space and an RGB space respectively. The color space transformation table illustrated in FIG. 7A shows that the value (Lk, ak, bk) (1≦k≦n) of the first color space corresponds to the value (Rk, Gk, Bk) of the second color space for each of n colors. When the color image output section 120 is a color printer, each of the colors of the output image is expressed typically by a CMYK value (Ck, Mk, Yk, Kk) and hence the second color space is a CMYK space.

The number n of the colors in the color space transformation table will be explained below. If the value of each element of a color in a three-dimensional color space such as a Lab space of an RGB space is expressed in 8 bits, the number of colors will be as many as (2ˆ8)ˆ3≈1677×10⁴. The volume of data to be used for such a large number of colors will be too large and adversely affect the processing speed so that the color space transformation table shows only a limited number of colors. Each of the colors of the limited number is arranged at an intersection produced by dividing each of the axes of the color space by an appropriate number. The intersection is referred to as grid point. In the case of a three-dimensional color space, if the divisor is 32 for each of the three axes, a level of accuracy necessary for color image correction processes can be achieved by means of 33 grid points on each of the three axes. Then, the total number of grid points, or the value of n in the color space transformation table is 33ˆ3≈360,000. In view of the number of pixels of a computer display that conforms to the VGA Standard, which is about 310,000, it will be seen that the number of colors is very small in the color space transformation table.

Now, color modification processing data and color modification history data will be described by referring to FIGS. 7B through 7D. Color modification processing data are data that take a central part in the object to be processed in a color image modification process according to the present invention. Color modification processing data comprise the values of n different colors, which is the same as those of the color space transformation table. A color space that expresses the value of a color changes in the stages of the color modification process. The initial color space is the first color space of the color space transformation table but it becomes the second color space in the final stage as shown in FIG. 7D. The color modification processing data that are obtained when a color modification process ends can be used as important modification history information. For the purpose of the present invention, the color modification processing data that are obtained at the stage when a color modification process ends are referred to as color modification history data. While the order of arrangement of colors in the color modification processing data and the order of arrangement of colors in the color space transformation table do not need to be the same, they are regarded to be the same in the following description.

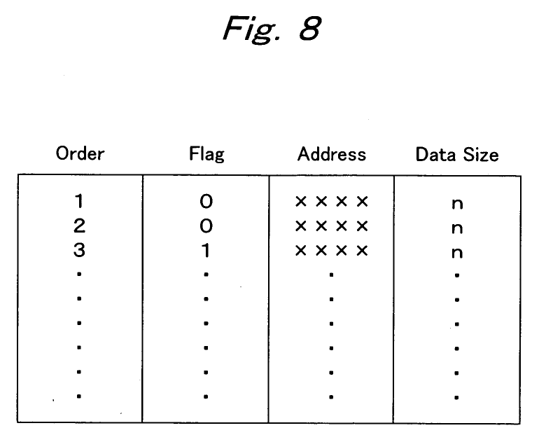

A color modification history data list provides important information and hence is comparable with color modification history data when using modification history. As shown in FIG. 8, a color modification history data list includes a column of “order” that contains numbers arranged in time series for modification processes, a column of “flag” that contains flags, each of which is used to identify if the related modification process is the most recent modification process or not in the modification processes in the past, a column of “address” that contains the addresses where color modification history data are stored and a column of “data size” for indicating the number of colors in the color modification history data. Each flag shows a value of 1 when it relates to the most recent modification. Otherwise, it shows a value of 0. In the modification history data list illustrated in FIG. 8 as example, the modification process with the order number of 3 is the most recent modification process in the modification processes in the past and the number of colors in the color modification history data is n for all the order numbers.

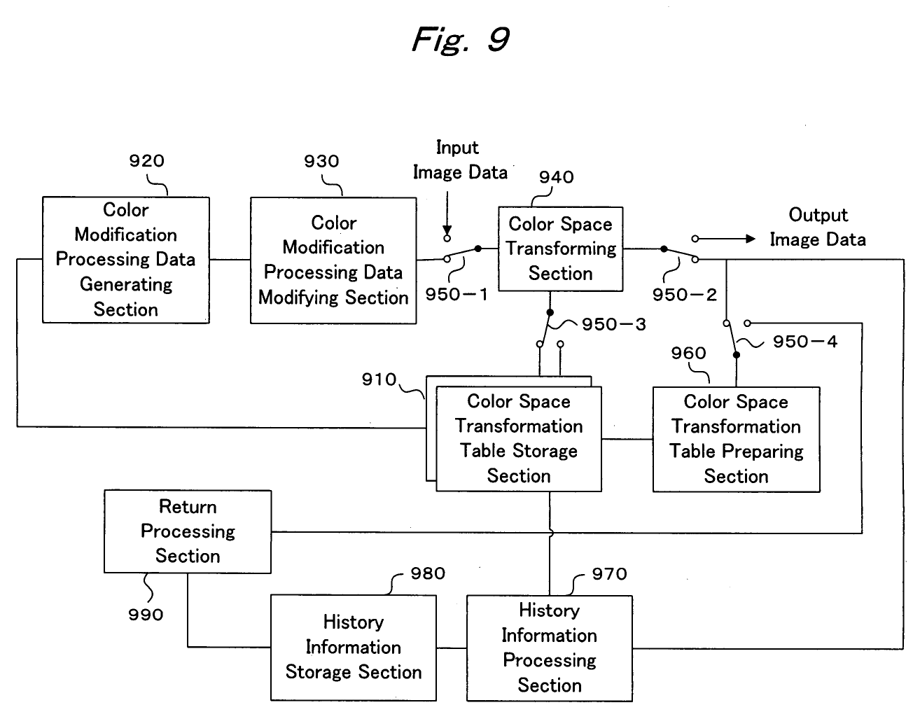

Now, the color image correction processing apparatus 150 of this embodiment will be described in terms of the configuration of the functional blocks thereof by referring to FIG. 9. However, it will be appreciated that the configuration of the functional blocks may be modified appropriately so long as the functions of the present invention work properly.

Color space transformation table storage section 910 stores color space transformation tables. In the initial stages of a color modification process, it stores the color space transformation table containing the data that are contained in the profile selected and read in from the profile preserving section 130. It additionally stores the color space transformation table that is prepared anew by the color modification process. The color space transformation table storage section 910 corresponds to the color space transformation table data region in the RAM 530. An example of color space transformation table is already described above by referring to FIG. 7A. The color space transformation table defines the corresponding relationship between the Lab value in the Lab space that is the first color space and the RGB value in the RGB space that is the second color space for each of the n colors.

In FIG. 9, color modification processing data generating section 920 generates color modification processing data that include the data of the first color space of the above-described color space transformation table as part thereof. FIG. 7B shows the color modification processing data that are generated by the color modification processing data generating section 920 from the color space transformation table illustrated in FIG. 7A. More specifically, the color modification processing data are listed data prepared by using the Lab values in the Lab space, which is the first color space, for the n colors. The relationship between the data in the color space transformation table and the color modification processing data may be clear by comparing FIG. 7A and FIG. 7B.

When the predetermined data of the first color space are arranged in a predetermined order, the color space transformation table does not necessarily have to contain the data of the first color space. In other words, it is sufficient to arrange the RGB values in a predetermined order in an RGB space that is a two-color space.

Thus, when the data and the order of arrangement of the data of the first color space are predetermined, the color space transformation table may only contain the RGB values. Then, therefore, the Lab values are not explicitly shown and hence only the RGB values are explicitly shown in the color space transformation table illustrated in FIG. 7A but it is possible to prepare the color modification data of FIG. 7B by means of the predetermined data of the first color space and the order of arrangement thereof.

In FIG. 9, color modification processing data modifying section 930 reads in the modification method and the color modification parameters specified by the operator from the operation input section 140 by way of the operation input section I/F 590 and modifies the color modification processing data according to the modification method and the color modification parameters that are read in. More specifically, the color modification processing data modifying section 930 modifies the color modification processing data generated by the color modification processing data generating section 920 as illustrated in FIG. 7B to the color modification processing data illustrated in FIG. 7C. While the color values contained in the color modification processing data illustrated in FIG. 7C may change by a modification, they are still expressed by Lab values in the Lab space that is the first color space. Additionally, all the Lab values of the color modification processing data illustrated in FIG. 7C may not be different from the Lab values of the initial color modification processing data illustrated in. FIG. 7B because only the colors in the range that is defined by the modification method and the color modification parameters are the objects of the modification process.

The color space transforming section 940 transforms the color information expressed by the first color space into color information of the second color space by means of the most recently updated one of the color space transformation tables stored in the color space transformation table storage section 910. The color modification processing data illustrated in FIG. 7C that are generated in a modification process by the above-described color modification processing data modifying section 930 are transformed into color modification processing data in the RGB space as illustrated in FIG. 7D, or into color modification history data, by the color space transforming section 940.

Additionally, the color space transforming section 940 transforms the input image data, where color information is expressed by the first color space, into output image data, where color information is expressed by the second color space. More specifically, switch 950-1 selects the input image data as input to the color space transforming section and switch 950-2 is set in such a way that the output from the color space transforming section is transmitted to the color image output section 120. In other words, the color space transforming section 940 also has the function of executing image outputting processes and it can determine if the last modification was appropriate or not by seeing the image output from the color image output section 120. The output image data are output after being subjected to a color space transformation process by the color space transforming section 940 and a color space process is conducted by using the color space transformation table so that the colors of the output image change when the data of the color space transformation table that is being used are changed. Note that the input image data that are input to the color space transforming section 940 are the image data that are selected in advance according to the input image selection information transmitted from the operation input section 140.

The color space transforming section 940 transforms the color values expressed by the first color space into color values expressed by the second color space in a manner as described below. Firstly, the Lab values that are located at respective grid points of the first color space (Lab space) in the color space transformation table in the proximity of the colors of (Li, ai, bi) to surround the respective colors are extracted for the colors having the Lab values of (Li, ai, bi). For example, eight Lab values may be extracted and the eight table data formed respectively by the Lab values and the color values of the second color space (RGB space) that correspond to the Lab values are taken out from the color space transformation table. Note that L0<L1, a0<a1 and b0<b1.

L0, a0, b0: R0, G0, B0

L0, a0, b1: R1, G1, B1

L0, a1, b0: R2, G2, B2

L0, a1, b1: R3, G3, B3

L1, a0, b0: R4, G4, B4

L1, a0, b1: R5, G5, B5

L1, a1, b0: R6, G6, B6

L1, a1, b1: R7, G7, B7

Then, computation for interpolation, using the linear transformation formula shown below is carried out for the color having a Lab value of (Li, ai, bi) to determine the RGB value (Ri, Bi, Bi) of the second color space (RGB space).

$$\begin{matrix}\begin{matrix}Ri = R 0 + ( R 1 - R 0 ) * ( bi - b 0 ) / ( b 1 - b 0 ) + \\ ( R 2 - R 0 ) * ( ai - a 0 ) / ( a 1 - a 0 ) + \\ ( R 4 - R 0 ) * ( Li - L 0 ) / ( L 1 - L 0 ) + \\ ( R 3 - R 2 - R 1 + R 0 ) * ( ai - a 0 ) / \\ ( a 1 - a 0 ) * ( bi - b 0 ) / ( b 1 - b 0 ) + \\ ( R 5 - R 4 - R 1 + R 0 ) * ( Li - L 0 ) / \\ ( L 1 - L 0 ) * ( bi - b 0 ) / ( b 1 - b 0 ) + \\ ( R 6 - R 4 - R 2 + R 0 ) * ( Li - L 0 ) / \\ ( L 1 - L 0 ) * ( ai - a 0 ) / ( a 1 - a 0 ) + \\ ( R 7 - R 6 - R 5 - R 3 + R 1 + R 4 + R 2 - R 0 ) * \\ ( Li - L 0 ) / ( L 1 - L 0 ) * ( ai - a 0 ) / \\ ( a 1 - a 0 ) * ( bi - b 0 ) / ( b 1 - b 0 )\end{matrix} \\ \\ \begin{matrix}Gi = G 0 + ( G 1 - G 0 ) * ( bi - b 0 ) / ( b 1 - b 0 ) + \\ ( G 2 - G 0 ) * ( ai - a 0 ) / ( a 1 - a 0 ) + \\ ( G 4 - G 0 ) * ( Li - L 0 ) / ( L 1 - L 0 ) + \\ ( G 3 - G 2 - G 1 + G 0 ) * ( ai - a 0 ) / \\ ( a 1 - a 0 ) * ( bi - b 0 ) / ( b 1 - b 0 ) + \\ ( G 5 - G 4 - G 1 + G 0 ) * ( Li - L 0 ) / \\ ( L 1 - L 0 ) * ( bi - b 0 ) / ( b 1 - b 0 ) + \\ ( G 6 - G 4 - G 2 + G 0 ) * ( Li - L 0 ) / \\ ( L 1 - L 0 ) * ( ai - a 0 ) / ( a 1 - a 0 ) + \\ ( G 7 - G 6 - G 5 - G 3 + G 1 + G 4 + G 2 - G 0 ) * \\ ( Li - L 0 ) / ( L 1 - L 0 ) * ( ai - a 0 ) / \\ ( a 1 - a 0 ) * ( bi - b 0 ) / ( b 1 - b 0 )\end{matrix} \\ \\ \begin{matrix}Bi = B 0 + ( B 1 - B 0 ) * ( bi - b 0 ) / ( b 1 - b 0 ) + \\ ( B 2 - B 0 ) * ( ai - a 0 ) / ( a 1 - a 0 ) + \\ ( B 4 - B 0 ) * ( Li - L 0 ) / ( L 1 - L 0 ) + \\ ( B 3 - B 2 - B 1 + B 0 ) * ( ai - a 0 ) / \\ ( a 1 - a 0 ) * ( bi - b 0 ) / ( b 1 - b 0 ) + \\ ( B 5 - B 4 - B 1 + B 0 ) * ( Li - L 0 ) / \\ ( L 1 - L 0 ) * ( bi - b 0 ) / ( b 1 - b 0 ) + \\ ( B 6 - B 4 - B 2 + B 0 ) * ( Li - L 0 ) / \\ ( L 1 - L 0 ) * ( ai - a 0 ) / ( a 1 - a 0 ) + \\ ( B 7 - B 6 - B 5 - B 3 + B 1 + B 4 + B 2 - B 0 ) * \\ ( Li - L 0 ) / ( L 1 - L 0 ) * ( ai - a 0 ) / \\ ( a 1 - a 0 ) * ( bi - b 0 ) / ( b 1 - b 0 )\end{matrix}\end{matrix}$$

The above-described color space transformation method remains same when the input to the color space transforming section 940 is input image data and when it is color modification processing data.

The color space transformation table preparing section 960 prepares a new color space transformation table by using the color modification processing data of the second color space obtained by the color space transforming section 940. The preparation of the color space transformation table is realized by substituting the values of the second color space in the most recent color space transformation table stored in the color space transformation table storage section 910 with the values of the color modification processing data of the second color space obtained by the color space transforming section 940. FIG. 7E shows an example of newly prepared color space transformation table.

The newly prepared color space transformation table is stored in the color space transformation table storage section 910 and switch 950-3 is set so that the color space transforming section 940 may use the new color space transformation table. As input image data are input to the color space transforming section 940 in this state, output image data that are subjected to a color modification process are output.

As may be clear from the above description, output image data are subjected to a color modification process only by an operation of modifying color modification processing data by the above-described color modification processing data modifying section.

When modification history information is stored in the profile preserving section 130, history information processing section 970 reads in the color modification history data list and the color modification history data from the profile preserving section 130 and stores the modification history information in history information storage section 980. The history information storage section 980 corresponds to the color modification history data list region and the color modification history data region in the RAM 530. The history information processing section 970 additionally stores the color modification history data newly generated by the color space transforming section 940 in the history information storage section 980. Still additionally, it updates the color modification history data after the generation of the new color modification history data by the color space transforming section 940 and stores the outcome of the updating in the history information storage section 980.

In FIG. 9, when a return processing section 990 recognizes that the operator depresses [return] button of the operation input section 140, it acquires the most recent color modification history data in the results of the past color modification processes, referring to the color modification history data list stored in the history information storage section 980. Additionally, the return processing section 990 controls switch 950-4 and transmits the above-described color modification history data to the color space transformation table preparing section 960. The color space transformation table preparing section 960 prepares a color space transformation table according to the above-described color modification history data and stores the prepared color space transformation table in the color space transformation table storage section 910. Since the color space transformation table stored in the color space transformation table storage section 910 is the one prepared on the basis of the most recent color modification history data in the results of the past color modification processes, it is the most recent color space transformation table in the result of the past color modification processes. In other words, the return processing section 990 returns to the most recent state in the results of the past color modification processes.

Additionally, when a color modification process ends, the return processing section 990 relates the color modification history data list and the color modification history data stored in the history information storage section 980 to each other and transmits them to the profile preserving section 130.

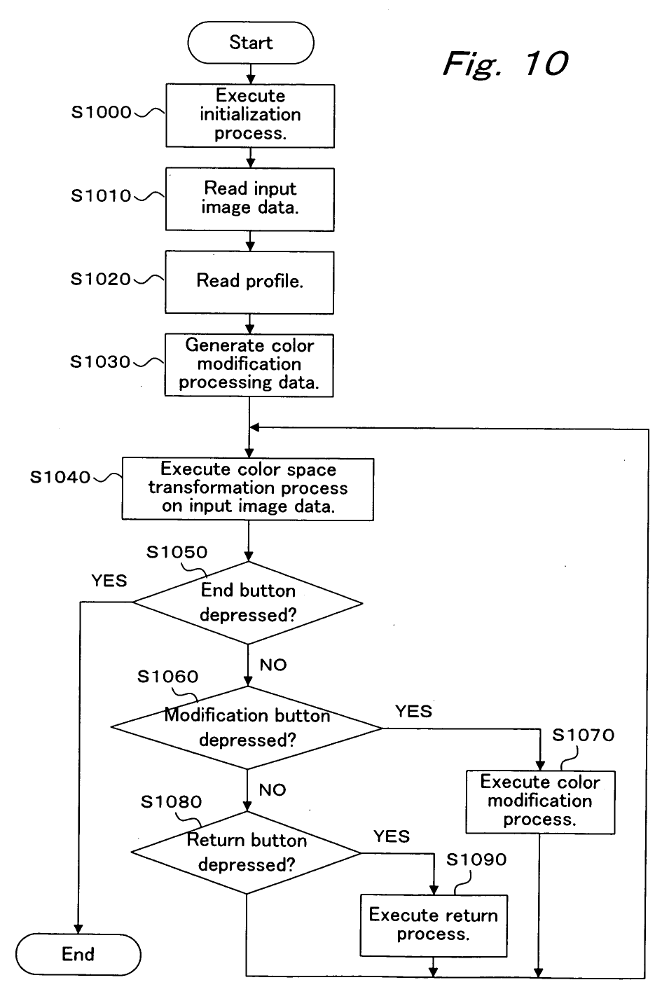

Now, the operation of the color image correction processing apparatus 150 of this embodiment will be summarily described below by referring to FIG. 10. Any of the processing steps in FIG. 10 that requires a more detailed description, the step will be described in greater detail by referring to some other related drawing. It may be needless to say that the operation of the flowchart of FIG. 10 may be modified appropriately so long as the functions of the present invention work.

Firstly, in Step S1000, a CPU 520 of the color image correction processing apparatus 150 initializes the RAM 530 and all the interfaces.

Subsequently, in Step S1010, which is a step for an input image data reading in process, the CPU 520 stores the input image data selected according to the input image selection information that is obtained from the operation input section 140 by way of the operation input I/F 590 in the input image region in the RAM 530 by way of the image input I/F 560.

Then, in Step S1020, which is a step for a profile reading in process, the CPU 520 reads in the profile of the color image output section 120 by way of the profile preserving section I/F 580 and stores the data of the color space transformation table contained in the profile of the color image output section 120 in the color space transformation table storage section 910.

In Step S1030, the control section 150 generates color modification processing data by means of the color modification processing data generating section 920. The data of the first color space in the color space transformation table stored in the color space transformation table storage section 910 in Step S1020 are used for the generated color modification processing data without modification. The generated color modification processing data are stored in the color modification processing data region in the RAM 530. In this stage, the Lab value of each color in the color modification processing data is equal to the corresponding color value of the first color space in the color space transformation table.

If modification history information is stored in the profile preserving section 130, the CPU 520 reads in the modification history information by way of the profile preserving I/F 580 and stores the color modification history data list and the color modification history data in the history information storage section 980.

In Step S1040 that comes immediately after the file reading in process, the CPU 520 subjects the input image data input to the color space transforming section 940 to a color space transformation process and outputs the output image data obtained as a result of the process to the color image output section 120. FIG. 11 shows the flow of the color space transformation process. The color space transforming section 940 reads in the color space transformation table from the color space transformation table storage section 910 in Step S1110 and executes a color space transformation process on the input image data, using the color space transformation table, in Step S1120. Then, the color space transforming section 940 writes the output image data generates as a result of the color space transformation process in the image output RAM 540 in Step S1130. The output image data written in the image output RAM 540 are then transmitted to the color image output section 120 by way of the image output I/F 570 and an image is output.

When the color space transformation process that is executed on the input image data ends, the CPU 520 recognizes if each of the [end], [modify] and [return] buttons is depressed in the corresponding Step S1050, S1060 or S1070 or not by way of the operation input section I/F 590.

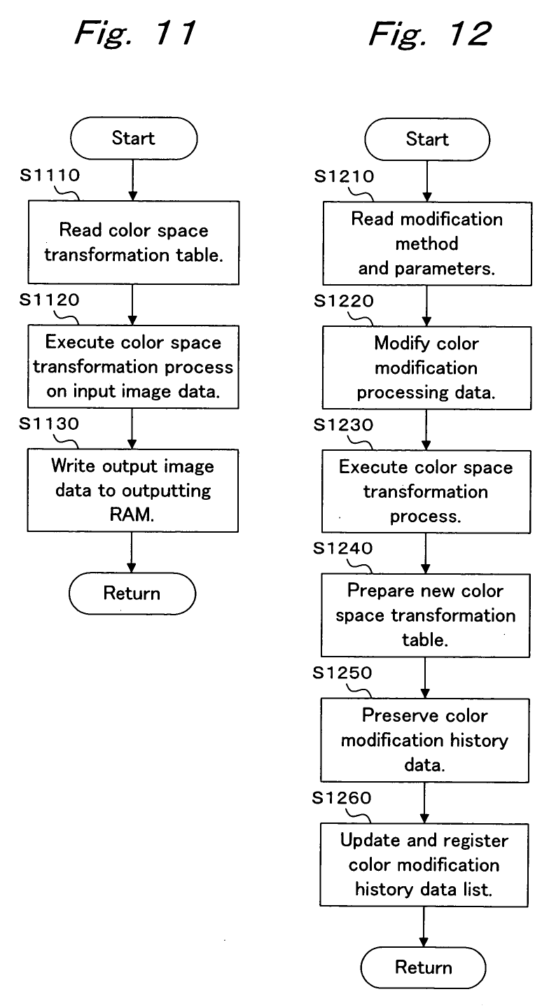

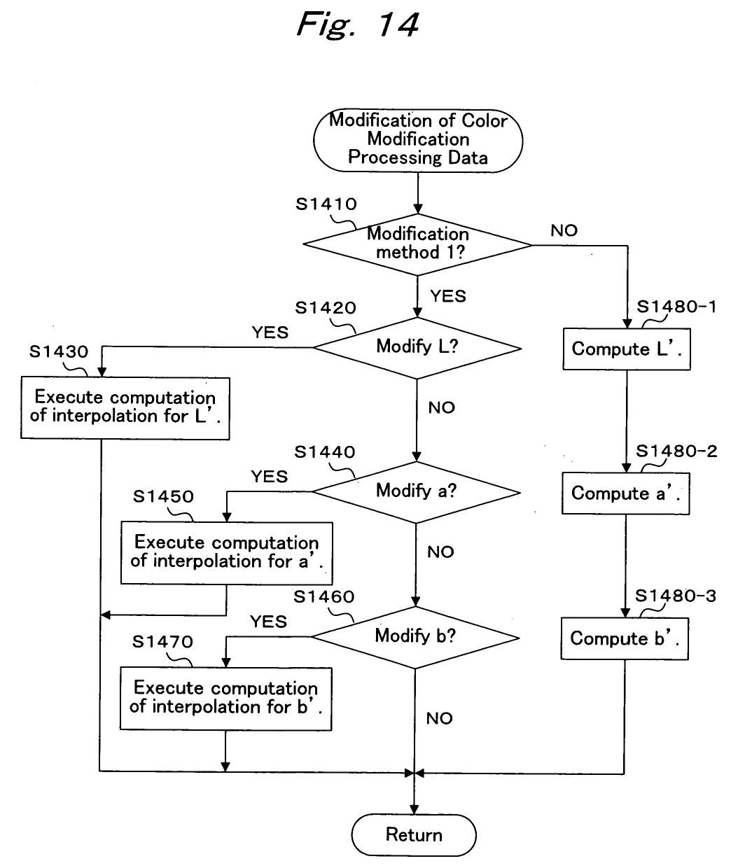

If the CPU 520 recognizes that the [modify] button is depressed in Step S1060, it executes a color modification process in Step S1070 and, when the color modification process ends, it returns to the color space transformation process being executed on the input image data in Step S1040. FIG. 12 shows a color modification process. Firstly in Step S1210 of the color modification process, the CPU 520 reads in the modification method and the color modification parameters specified by the operator from the operation input section 140 by way of the operation input section I/F 590. Then, in the next step, or Step S1220, the CPU 520 modifies the color modification processing data by means of the color modification processing data modifying section 930 according to the modification method and the color modification parameters that are read in. The modification process of the color modification processing data according to the modification method and the color modification parameters that are read in will be described in greater detail hereinafter by referring to FIG. 14. Then, in the next step, or Step S1230, the CPU 520 executes a color space transformation process on the modified color modification processing data by means of the color space transforming section 940, using the color space transformation table stored in the color space transformation table storage section 910 and transforms them into color modification processing data (color modification history data) of the second color space.

More specifically, the color modification processing data of the Lab space illustrated in FIG. 7C are transformed into color modification processing data in the RGB space as shown in FIG. 7D by the color space transformation process. The color space transformation table that is used here is the initial color space transformation table that is contained in the profile read in in Step S1020 as illustrated in FIG. 10.

In the next step, or Step S1240, the CPU 520 prepares a new color space transformation table by means of the color space transformation table preparing section 960 according to the color modification processing data that are obtained as a result of the color space transformation process executed on the modified color modification processing data and transformed into color values of the second color space. The preparation of the color space transformation table is realized by substituting the values of the second color space in the initial color space transformation table contained in the profile that is read in in Step S1020 of FIG. 10 with the values of the color modification processing data of the second color space as illustrated in FIG. 7D. In this way, a new color space transformation table as shown in FIG. 7E is prepared.

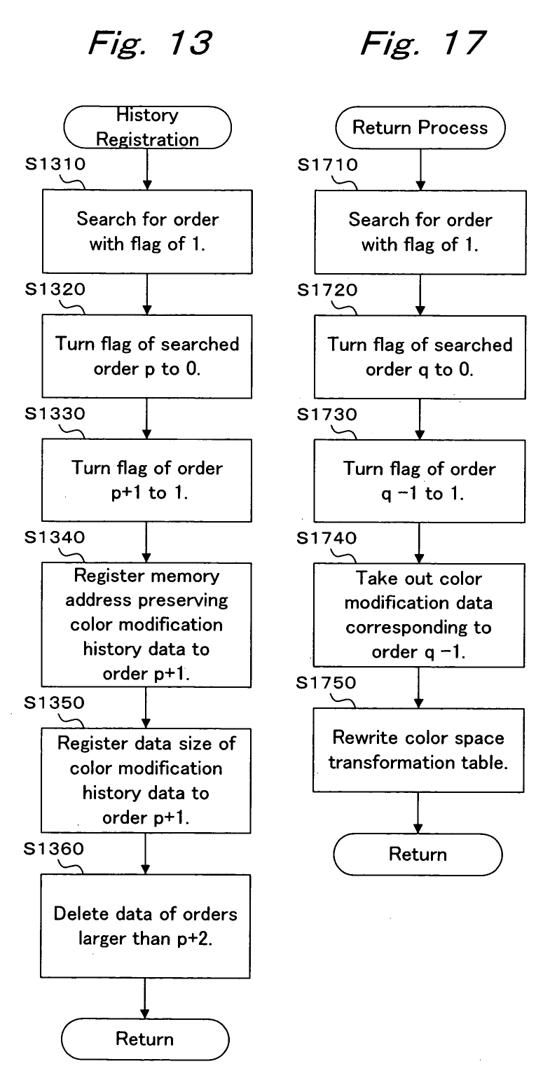

When registering modification history, the color modification processing data that are transformed into color information of the second color space in Step ST 1250, or the color modification history data, are stored in the history information storage section 980. Additionally, the color modification history data list that is updated by the method illustrated in FIG. 13 is registered in Step S1260. Now, the method of updating the color modification history data list will be described by referring to FIG. 13. Firstly, in Step S1310, the CPU 520 looks for the order where the value of the flag is equal to 1. Assume that the order is p. Then, the CPU 520 reduces the value of the flag in the row of the order p to 0 in Step S1320 and reduces the value of the flag in the row of the order (p+1) to 1 in Step S1330. Subsequently, in Steps S1340 and S1350, the CPU 520 adds the address in the memory where the above-described color modification history data are preserved and the data size in the row of the order (p+1). Thereafter, in Step S1360, the CPU 520 deletes the data of the orders that are not smaller than (p+2) and ends the process of updating the color modification history data list. While the operation of preserving the color modification history data (S1250) and that of updating and registering the color modification history data list (S1260) are conducted after the preparation of the new color space transformation table (S1240) in FIG. 12, the operation of preserving the color modification history data and that of updating and registering the color modification history data list may be conducted before the preparation of the new color space transformation table.

FIG. 14 is a flowchart of the modification process for color modification processing data in Step S1220 of FIG. 12. Firstly in Step S1410, the CPU 520 determines if the modification method is the modification method 1 or the modification method 2 on the basis of the information from the operation input section 190 that is read in by way of the operation input section I/F 590.

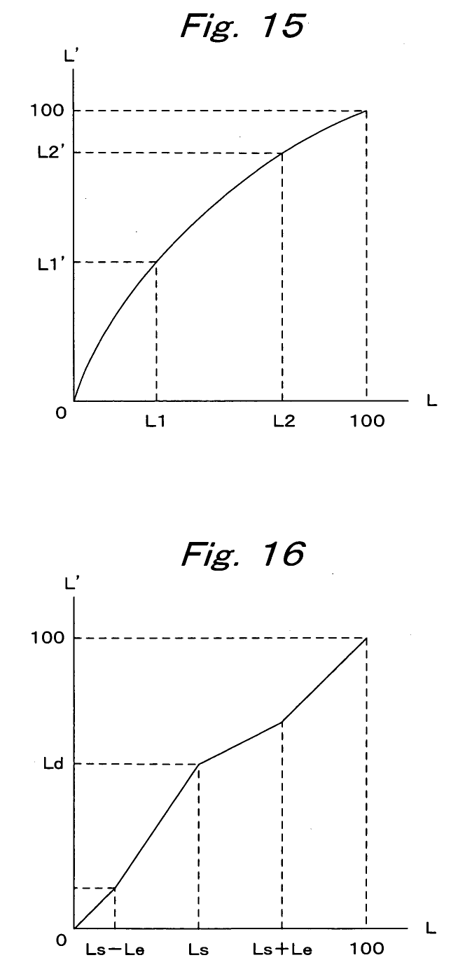

If the modification method 1 is selected, the CPU 520 determines if the element to be adjusted is L, a or b respectively at Steps S1420, S1440 and S1460. If the element to be adjusted is determined to be L in Step S1420, a computing operation for interpolation is conducted typically by means of spline interpolation so as to make it agree with one or more than one sets of input value Lr and output value Lr′ that are read in by way of the operation input section I/F. For example, if the output values for input values L1 and L2 are L1′ and L2 ′ respectively, the relationship between the input L value and the modified L value is determined as shown in FIG. 15 as a result of the computing operation for interpolation and the color modification processing data are modified. In the case of the modification method 1, the element to be adjusted is only one of L, a and b, the process of modifying the color modification processing data ends when the color modification processing data are modified for the L value. If the element to be adjusted is determined to be not L in Step S1420, the CPU 520 determines if the element to be adjusted is a or not in Step S1440. If the element to be adjusted is determined to be a, the color modification processing data are modified by means of a computing operation for interpolation as in the case where the element to be adjusted is L. If the element to be adjusted is determined to be b, a similar process is executed. In this way, the color modification processing data are modified in the Lab space.

If, on the other hand, it is determined that the modification method is the modification method 2 in Step S1410, the CPU 520 determines the Lab values after the modification process according to the Lab values for the color to be modified, the color after the modification and the influence range that are read in from the operation input section 140 by way of the operation input section I/F 590. More specifically, the CPU 520 determines the L value after the modification process, or L′, in Step S1480-1 and then determines the a value after the modification process, or a′, in Step S1480-2. Thereafter, the CPU 520 determines the b value after the modification process, or b′, in Step S1480-3. If the color to be transformed is Ls, the color after the transformation is Ld, and the influence range is Le, the L value of the modification, or L′, is computationally determined from L by means of the formula below and the L value of the color modification processing data is modified. FIG. 16 illustrates the relationship between the original L value and the L value after the modification, or L′.

if L=Ls
L′=Ld

else if Ls−Le<L<Ls
L′=(Ld−Ls+Le)*(L−Ls+Le)/Le+(Ls−Le)

else if Ls<L<Ls+Le
L′=(Ls+Le−Ld)*(L−Ls)/Le+Ld

else
L′=L

Likewise, the a value and the b value after the modification, or a′ and b′, are computationally determined as in the case of the modification of the L value and the color modification processing data are modified in the Lab space.

Referring back to FIG. 10, if the CPU 520 recognizes in Step S1080 that the “return” button is depressed, it executes a return process and, after the end of the return process, goes back to the color space transformation process for the input image data in Step S1040. FIG. 17 is a detailed flowchart of the return process. Firstly in Step S1710, the return processing section 990 searches for the order in the color modification history data list where the flag is equal to 1. Assume that the order in the color modification history data list where the flag is equal to 1 is q. Then, in the next step, or Step S1720, the return processing section 990 reduces the value of the flag in the row of the order q to 0 and subsequently, in Step S1730, it changes the flag of the order (q-1) to 1. Subsequently, in Step S1740, the return processing section 990 acquires the most recent color modification history data of the past color modification processes stored in the history information storage section 980 by referring to the address and the data size of the row of the order (q-1). Then, in Step S1750, the return processing section 990 inputs the color modification history data to the color space transformation table preparing section 960 and rewrites the color space transformation table. The rewriting of the color space transformation table is realized by substituting the data of the second color space in the color space transformation table at the time of starting the return process with the above-described color modification history data.

If the CPU 520 recognizes in Step S1050 of FIG. 10 that the “end” button is depressed, it ends the color modification process. When registering the modification history, it transmits the data of the color space transformation table stored in the color space transformation table storage section 910 and the color modification history data and the color modification history data list associated with the color modification history data stored in the history information storage section 980 to the profile preserving section 130 and preserves them there.

As described above, according to the present invention, the information to be used in the input image data themselves are not modified in a color modification process of an image and hence no comparison process is executed for determining if each of the vast number of pixels of the input image is an object of a color modification process or not. Thus, the present invention provides a color image correction processing apparatus and a color image correction processing method that does not require a large capacity memory and hence can reduce the processing time.

Additionally, the above-described embodiment of the present invention uses only the color modification history data to be loaded from the corresponding memory for a color modification return process and does not execute any process on a pixel by pixel basis for the vast number of pixels of the input image. Thus, the present invention can provide a color image correction processing apparatus and a color image correction processing method that does not require a large capacity memory and can quickly restore the state of the outcome of a past modification.

Although exemplary embodiments of the present invention have been shown and described, it will be apparent to those having ordinary skill in the art that a number of changes, modifications or alterations to the invention as described herein may be made, none of which depart from the spirit of the present invention. All such changes, modifications and alterations should therefore be seen as within the scope of the present invention.

1. A color image correction processing apparatus comprising:
a device for storing the data of a first color space transformation table relating a first color space defining the values of the colors of an input image to a second color space defining the values of the colors of an output image;
a color modification processing data generating section for reading the data of the color space transformation table from the color space transformation table storage device and generating color modification processing data including the data of the first color space contained in the color space transformation table;
a color modification processing data modifying section for modifying color modification processing data generated by the color modification processing data generating section;
a color space transformation section having the function of transforming the values of the colors in the first color space to the values of the colors in the second color space for transforming the color modification processing data modified by the color modification processing data modifying section into color modification history data including the data of the second color space by referring to the first color space transformation table; and
a color space transformation table preparing section for preparing a second color space transformation table by substituting the color modification history data acquired as a result of the transformation by the color space transforming section with the data of the second color space and storing the data of the second color space transformation table in the color space transformation table storage device;
the color space transforming section being adapted to generate color modified output image data from the input image data input to it by referring to the second color space transformation table.

2. The apparatus according to claim 1, wherein
the color modified output image data are generated by modifying only the color modification processing data.

3. The apparatus according to claim 2, wherein
the color modification processing data modifying section modifies the color modification processing data according to modification method selection information and color modification parameters input to it.

4. The apparatus according to claim 3, further comprising:
a history information processing section for processing information relating to the color modification processing data modified by the color modification processing data modifying section; and
a history information storage section for storing the information relating to the color modification processing data and processed by the history information processing section.

5. The apparatus according to claim 1, wherein
the color modification processing data modifying section modifies the color modification processing data according to the modification method selection information and the color modification parameters input to it.

6. The apparatus according to claim 5, further comprising:
a history information processing section for processing information relating to the color modification processing data modified by the color modification processing data modifying section; and
a history information storage section for storing the information relating to the color modification processing data and processed by the history information processing section.

7. The apparatus according to claim 4, wherein
the information relating to the color modification processing data processed by the history information processing section and stored in the history information storage section includes the color modification history data obtained as a result of the past color modification processes or the color modification history data list containing the flag for identifying the most recent modification or not and the address information of the memory storing the color modification history data.

8. The apparatus according to claim 1, further comprising:
a history information processing section for processing information relating to the color modification processing data modified by the color modification processing data modifying section;
a history information storage section for storing the information relating to the color modification processing data and processed by the history information processing section; and
a return processing section for executing a process of returning to the state of the outcome of a past modification according to the operation selection information input to it by referring to the history information storage section storing the information relating to the color modification processing data processed by the history information processing section.

9. The apparatus according to claim 2, further comprising:
a history information processing section for processing information relating to the color modification processing data modified by the color modification processing data modifying section;
a history information storage section for storing the information relating to the color modification processing data and processed by the history information processing section; and
a return processing section for executing a process of returning to the state of the outcome of a past modification according to the operation selection information input to it by referring to the history information storage section storing the information relating to the color modification processing data processed by the history information processing section.

10. The apparatus according to claim 3, further comprising:
a history information processing section for processing information relating to the color modification processing data modified by the color modification processing data modifying section;
a history information storage section for storing the information relating to the color modification processing data and processed by the history information processing section; and
a return processing section for executing a process of returning to the state of the outcome of a past modification according to the operation selection information input to it by referring to the history information storage section storing the information relating to the color modification processing data processed by the history information processing section.

11. The apparatus according to claim 8, wherein
the information relating to the color modification processing data processed by the history information processing section and stored in the history information storage section includes the color modification history data obtained as a result of the past color modification processes or the color modification history data list containing the flag for identifying the most recent modification or not and the address information of the memory storing the color modification history data;
the return processing section acquires the color modification history data acquired by the most recent color modification process in the past executed by referring to the color modification history data list stored in the history information storage section and inputs the color modification history data to the color space transformation table preparing section; and
the color space transformation table preparing section prepares the color space transformation table according to the color modification history data input to it and stores data of the color space transformation table in the color space transformation table storage device.

12. A color image correction processing method comprising:
storing data of a first color space transformation table relating a first color space defining the values of the colors of an input image to a second color space defining the values of the colors of an output image;
reading the data of the color space transformation table;
generating color modification processing data including the data of the first color space contained in the color space transformation table;
modifying the generated color modification processing data;
transforming the modified color modification processing data modified into color modification history data including the data of the second color space by referring to the first color space transformation table; and
preparing a second color space transformation table by substituting the color modification history data acquired as a result of the transformation by the color space transforming section with the data of the second color space in the first color space transformation table;
storing the data of the prepared second color space transformation table; and
generating color modified output image data from the input image data by referring to the second color space transformation table.

13. The method according to claim 12, wherein
the color modified output image data are generated by modifying only the color modification processing data.

14. The method according to claim 13, wherein
the color modification processing data are modified according to the input modification method selection information and the input color modification parameters when modifying the generated color modification processing data.

15. The method according to claim 14, further comprising:
processing information relating to the modified color modification processing data; and
storing the processed information relating to the color modification processing data.

16. The method according to 12, wherein
the color modification processing data are modified according to the input modification method selection information and the input color modification parameters when modifying the generated color modification processing data.

17. The method according to claim 16, further comprising:
processing information relating to the modified color modification processing data; and
storing the processed information relating to the color modification processing data.

18. The method according to claim 12, further comprising:
processing information relating to the modified color modification processing data; and
storing the processed information relating to the color modification processing data.

19. The method according to claim 13, further comprising:
processing information relating to the modified color modification processing data; and
storing the processed information relating to the color modification processing data.

20. The method according to claim 15, wherein
the information relating to the color modification processing data to be stored includes the color modification history data obtained as a result of the past color modification processes or the color modification history data list containing the flag for identifying the most recent modification or not and the address information of the memory storing the color modification history data.

21. The method according to claim 12, further comprising:
processing information relating to the modified color modification processing data;
storing the processed information relating to the color modification processing data; and
executing a process of returning to the state of the outcome of a past modification according to the input operation selection information and referring to the information relating to the stored and processed color modification processing data.

22. The method according to claim 13, further comprising:
processing information relating to the modified color modification processing data;
storing the processed information relating to the color modification processing data; and
executing a process of returning to the state of the outcome of a past modification according to the input operation selection information and referring to the information relating to the stored and processed color modification processing data.

23. The method according to claim 14, further comprising:
processing information relating to the modified color modification processing data;
storing the processed information relating to the color modification processing data; and
executing a process of returning to the state of the outcome of a past modification according to the input operation selection information and referring to the information relating to the stored and processed color modification processing data.

24. The method according to claim 16, further comprising:
processing information relating to the modified color modification processing data;
storing the processed information relating to the color modification processing data; and
executing a process of returning to the state of the outcome of a past modification according to the input operation selection information and referring to the information relating to the stored and processed color modification processing data.

25. The method according to claim 21, wherein
the processed and stored information relating to the color modification processing data includes the color modification history data obtained as a result of the past color modification processes or the color modification history data list containing the flag for identifying the most recent modification or not and the address information of the memory storing the color modification history data;
the return process of returning to the state of the outcome of a past modification comprises:
referring to the stored color modification history data list;
acquiring the color modification history data acquired by the most recent color modification process in the past;
preparing the color space transformation table according to the acquired color modification history data; and
storing data of the prepared color space transformation table.
